(19) United States
(12) Patent Application Publication
(10) Pub. No.: US 2010/0236610 A1
(43) Pub. Date: Sep. 23, 2010

(54) Mounting System for Solar Modules

(76) Inventors: Robert Stancel, Los Altos, CA (US); Varun Sivaram, Monte Sereno, CA (US)

Correspondence Address: Director of IP, 5521 Hellyer Avenue, San Jose, CA, 95138, US

(21) Appl. No.: 12/676,138

(22) PCT Filed: Sep. 3, 2008
(86) PCT No.: PCT/US08/75154

§ 371 Date: Jun. 1, 2010

Related U.S. Application Data
(60) Provisional application No. 60/969,694, filed on Sep. 3, 2007.

(51) Int. Cl. H01L 31/048; F16M 13/00

(52) U.S. Cl. 136/251; 248/274.1

(57) ABSTRACT

Methods and devices are provided for rapid solar module installation. In one embodiment, a photovoltaic module is provided comprising of a plurality of photovoltaic cells a plurality of photovoltaic modules; at least a first type of mounting bracket in contact with the module; at least a second type of mounting bracket, wherein the brackets are configured to interlock and connect multiple modules together.

### FIELD OF THE INVENTION

This invention relates generally to photovoltaic devices, and more specifically, to solar cells and/or solar cell modules designed for rapid mounting and installation.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction boxes, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar panels in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction boxes, 57,912 aluminum frames, untold meters of cablings, and numerous other components. These traditional module designs inherit a large number of legacy parts that hamper the ability of installers to rapidly and cost-efficiently deploy solar modules at a large scale. In addition to the redundancy of equipment, the types of module mounting brackets used to secure the modules to ground or roof supports increases the time and difficulty associated with module installation.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly increase their ease of installation, and create much greater market penetration and commercial adoption of such products.

### SUMMARY OF THE INVENTION

Embodiments of the present invention address at least some of the drawbacks set forth above. The present invention provides for the improved solar module designs that reduce manufacturing costs and cumbersome mounting hardware for each module. These improved module designs are well suited for rapid installation. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

Although not limited to the following, the embodiments of the present invention provides a rapid mounting system wherein the modules may have pre-mounted structure that slidably engage a support member attached to the support surface or the ground. The structure may be a bracket or some molded or shaped portion of the module (intregrally formed with the module or added separately). Slidable engagement allows for reduced mounting time. Using clips, rapid release clamps or the like may also speed installation. In some embodiments, these modules may be used as building integrated material and replace items such as roofing tiles or windows, or other building materials. Optionally, the modules do not replace building materials but are used in conjunction with or over such building materials.

In another embodiment of the present invention, a photovoltaic module mounting system is provided comprising at least one photovoltaic module; at least a first type of mounting bracket in contact with the module; at least a second type of mounting bracket on an adjacent module, wherein the brackets are configured to interlock and connect multiple modules together.

By way of nonlimiting example, any of the embodiments herein may be adapted to have the following features. In one embodiment, the first type of mounting bracket is configured so that the bracket can only be disengaged from the second type of mounting bracket by a pivoting motion of one bracket relative to one another. Optionally, the bracket is configured to slidably engage a mounting structure. Optionally, the bracket includes an angled portion that mates with an angled portion on another bracket. Optionally, the brackets on one module are offset from brackets on another module so as not interfere with each other. Optionally, the brackets on one module and brackets on another module both engage on another and both simultaneously engage a mounting structure. Optionally, the bracket is configured to slidably engage a mounting structure and simultaneously engage a bracket of another module. Optionally, the brackets on one module and brackets on another module both engage on another mate in a configuration that prevent the modules from pivoting upward beyond a substantially horizontal plane. Optionally, a plurality of modules are coupled together by brackets which pivot together to define a string of modules that are locked in position, wherein only the modules at a first end and a second end of the string of modules are fixedly secured.

In yet another embodiment of the present invention, a multi-method mounting assembly is provided comprising: a bracket configured to provide attachment of a module to the bracket and then the bracket to mounting structure, wherein attachment of bracket to mounting structure is by way of at least two possible attachment methods. Optionally, the bracket is configured wherein attachment of bracket to mounting structure is by way of at least three possible attachment methods. Optionally, the bracket is configured wherein attachment of bracket to mounting structure is by way of at least four possible attachment methods.

A further understanding of the nature and advantages of the invention will become apparent by reference to the remaining portions of the specification and drawings.

### BRIEF DESCRIPTION OF THE DRAWINGS

FIG. 1 is an exploded perspective view of a module according to one embodiment of the present invention.

FIG. 2 shows a cross-sectional view f a module according to one embodiment of the present invention.

FIGS. 3 and 4 show various mounting systems suitable for use with embodiments of the present invention.

FIG. 5 through 10 show a module attachment assembly according to one embodiment of the present invention.

FIGS. 11 through 20 show a module attachment assembly according to another embodiment of the present invention.

FIGS. 21 through 22 show a module attachment assembly according to yet another embodiment of the present invention.

FIGS. 23A through 23C show a module attachment assembly according to another embodiment of the present invention.

FIGS. 26 through 30 show a universal module mounting assembly according to one embodiment of the present invention.

FIGS. 31 through 33 show locking mechanism according to one embodiment of the present invention.

FIGS. 34 and 35 show mounting supports for modules according embodiments of the present invention.

FIGS. 36 through 38 show side views of mounting clips according embodiments of the present invention.

FIGS. 39 through 40 show perspective views of mounting clips according embodiments of the present invention.

FIGS. 41 through 43 show top down views of mounting clips according embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings.

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

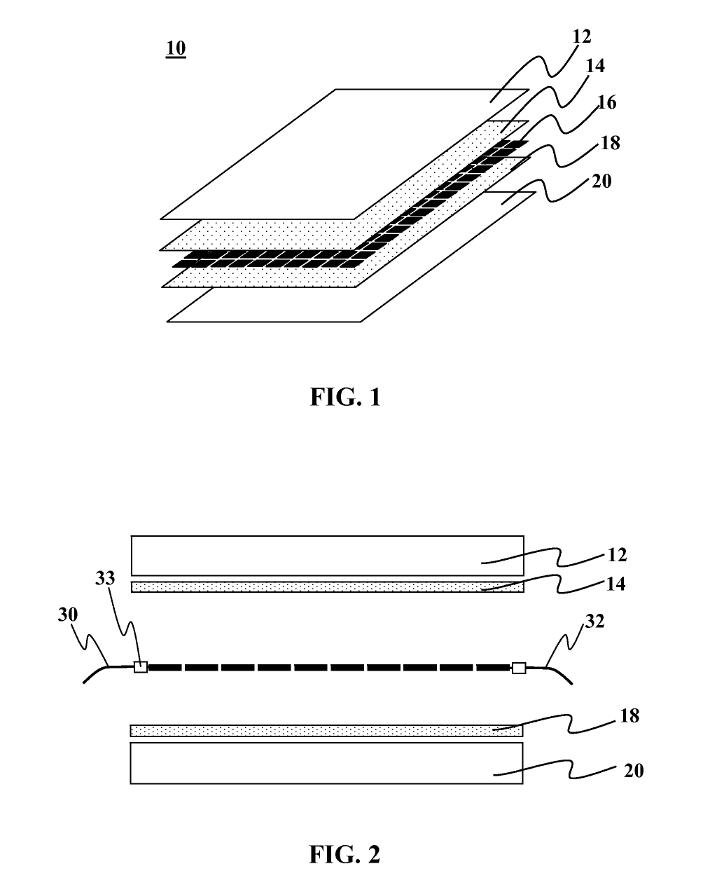

Referring now to FIG. 1, one embodiment of a module 10 according to the present invention will now be described. Traditional module packaging and system components were developed in the context of legacy cell technology and cost economics, which had previously led to very different panel and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, frame modifications, thickness modifications, and electrical connection modifications.

FIG. 1 shows that the present embodiment of module 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 provides structural support and acts as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. In one embodiment, the total thickness of the glass or multi-layer glass may be in the range of about 2.0 mm to about 13.0 mm, optionally from about 2.8 mm to about 12.0 mm. Optionally, in another embodiment, the total thickness of the glass or multi-layer glass may be in the range of about 0.1 mm to about 4.0 mm. Optionally, in another embodiment, the thickness of the front glass may be in the range of about 0.05 mm to about 0.7 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent module layer 12.

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, other absorber materials, IB-IIB-IVA-VIA absorbers, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the module can be found in commonly assigned, co-pending U.S. patent application Ser. No. 11/465,783 (Attorney Docket No. NSL-089) filed Aug. 18, 2006 and fully incorporated herein by reference for all purposes.

FIG. 2 shows a cross-sectional view of the module of FIG. 1. By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 2, this embodiment of module 10 is a frameless module without a central junction box. The present embodiment may use a simplified backsheet 20 that provides protective qualities to the underside of the module 10. As seen in FIG. 1, the module may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent module layer 12. Optionally, in such a configuration, the top sheet 12 may be a flexible top sheet such as that set forth in U.S. Patent Application Ser. No. 60/806,096 (Attorney Docket No. NSL-085P) filed Jun. 28, 2006 and fully incorporated herein by reference for all purposes. In one embodiment, electrical connectors 30 and 32 may be used to electrically couple cells to other modules or devices outside the module 10. It should also be understood that moisture barrier 33 may be placed around part or all of the perimeter of the module.

### Rapid Module Mounting System

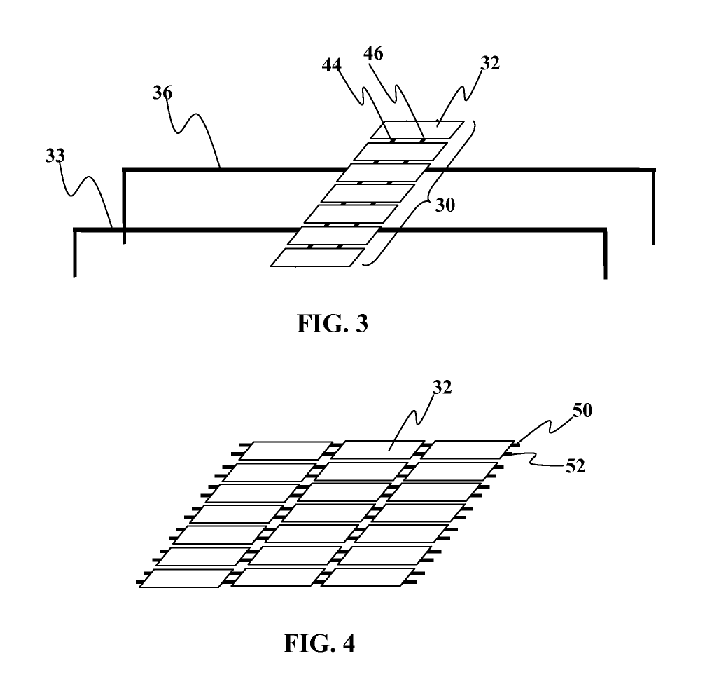

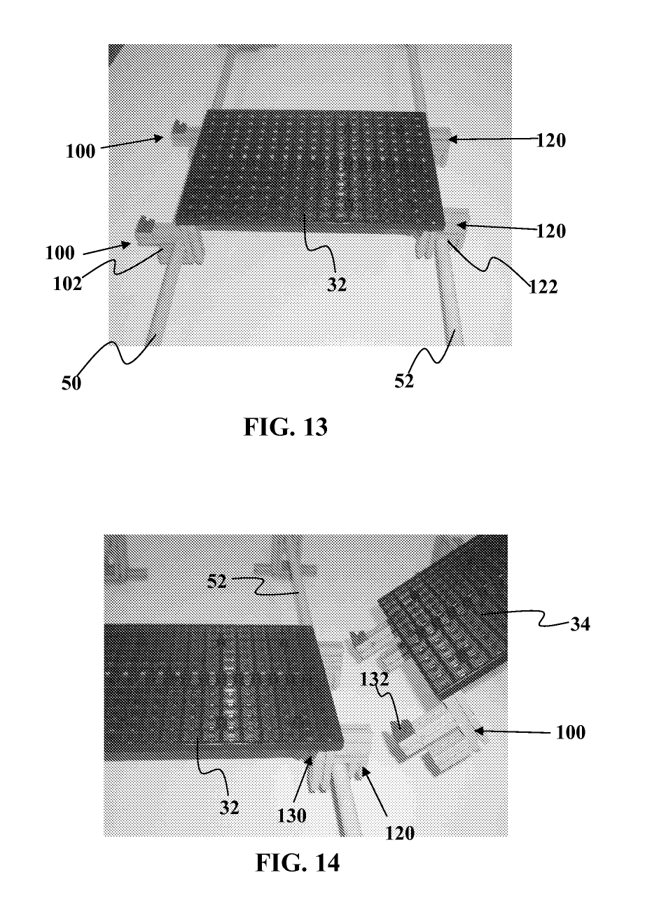

Referring now to FIG. 3, one embodiment of the present invention will now be described. FIG. 13 shows a solar assembly segment 30 comprised of a plurality of solar modules 32. The solar assembly segment 30 may be mounted on support beams or rails 33 and 36 that are mounted over the ground, a roof, or other installation surface. The segment 30 is itself mounted to crossing rails 44 and 46. This shows that each of the modules 32 may engage two rails. Thus, there may be two sets of brackets 100 and 110 per module. The number of brackets per modules may also be varied based on the number of rails. Some embodiments may have a zig-zag or alternating pattern with the brackets, using only one bracket per rail. This may reduce the number of brackets used per module.

FIG. 4 shows that modules 32 may also be mounted directly onto horizontal rails 50 and 52. These rails 50 and 52 may be mounted directly on a roof top or over the ground.

It should be understood that thin-film, silicon, or other absorber type solar modules may be adapted for use with the present mounting system. The modules may be framed or frameless. The may use edge mounted junction box(es), a central junction box, or multiple backside junction boxes. This embodiment of the rapid mounting system comprises of a plurality of brackets coupled to the module 32. The coupling may occur by various techniques and may include one or more of the following: adhesives, epoxy, mechanical retainers, screws, bolts, clamps, clips, or combinations thereof. The mounting hardware or locking mechanisms described herein may be comprised of various materials which provide sufficient strength to hold the module 32 in place. These materials include but are not limited to metals such as aluminum, steel, stainless steel, iron, copper, tin, or combinations thereof. Any metal material may be coated with a polymer or other coating material to provide electrical insulation, surface texturing or treatment, padding, or other purpose. Optionally, the mounting hardware or locking mechanisms may be comprised of hardened polymer, plastic, or the like instead of or used in combination with metal. The mounting hardware or locking mechanisms may be mounted to engage an underside, side edge, and/or top side surface of the module 32.

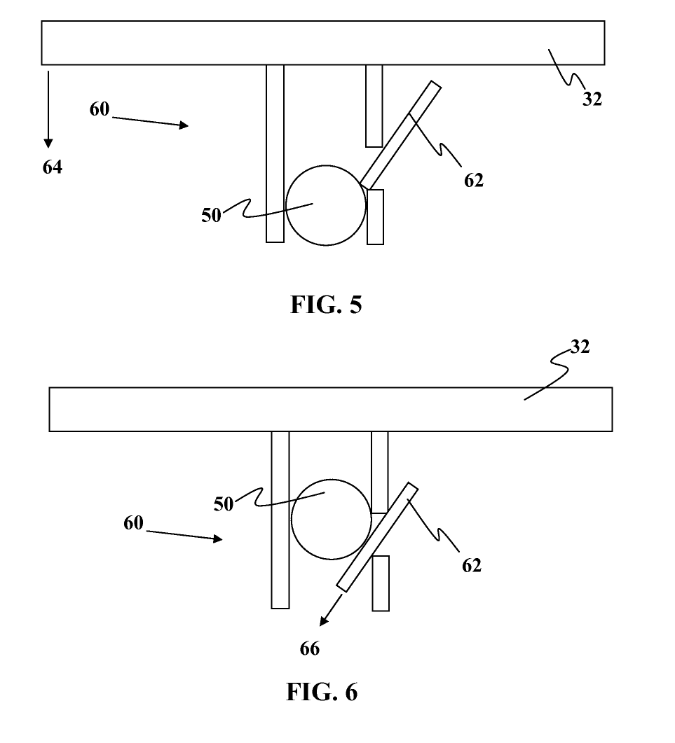

FIG. 5 shows one embodiment of a locking system for use with modules according to the present invention. The locking system 60 may be used to lock the module to latitudinal rails 44 and 46 or to longitudinal rails 50 and 52. The locking system 60 uses a sliding lock device 62 which slides out of the way when the module 32 and the locking system 60 are lowered over rail 50 as indicated by arrow 64. These mounting elements may be attached by a variety of techniques including but not limited to being glued on, melted on, mechanically attached, clamped with rubber, etc. . . .

FIG. 6 shows that as the module 32 is lowered, the rail 50 will move to a position where the sliding lock device 62 will slide into position below the rail 50 as indicated by arrow 66 to lock the rail 50 into position. To release the rail 50, the sliding lock device 62 may be raised by the end user to allow the module 32 to be lifted upwards and away.

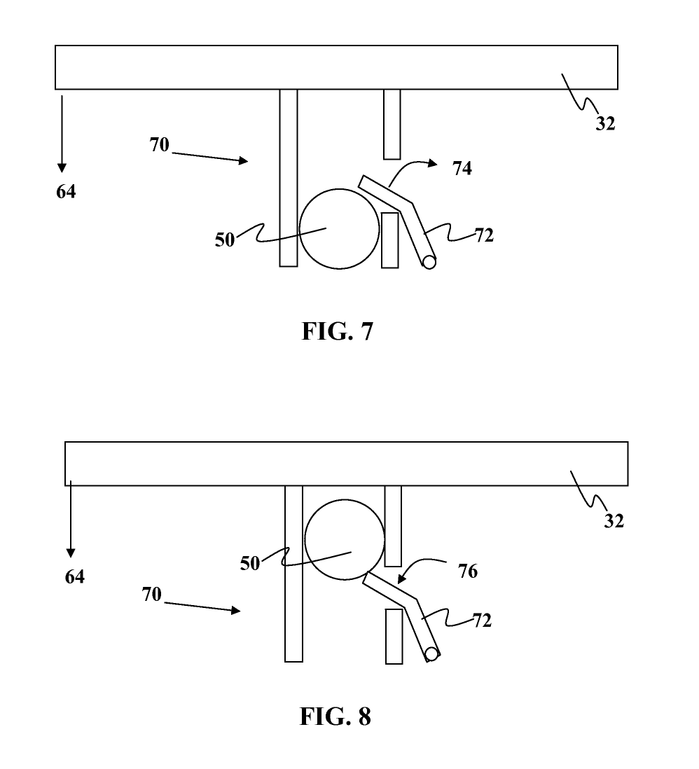

Referring now to FIG. 7, another embodiment of a locking mechanism will now be described. This embodiment shows a locking system 70 may be used to lock the module to latitudinal rails 44 and 46 or to longitudinal rails 50 and 52. The locking system 70 uses a rotating lock device 72 which rotates out of the way as indicated by arrow 74 when the module 32 and the locking system 60 are lowered over rail 50 as indicated by arrow 64.

FIG. 8 shows that as the module 32 is lowered, the rail 50 will move to a position where the rotating lock device 72 will rotate into a position below the rail 50 as indicated by arrow 76 to lock the rail 50 into position. To release the rail 50, the rotating lock device 72 may be rotated by the end user to allow the module 32 to be lifted upwards and away.

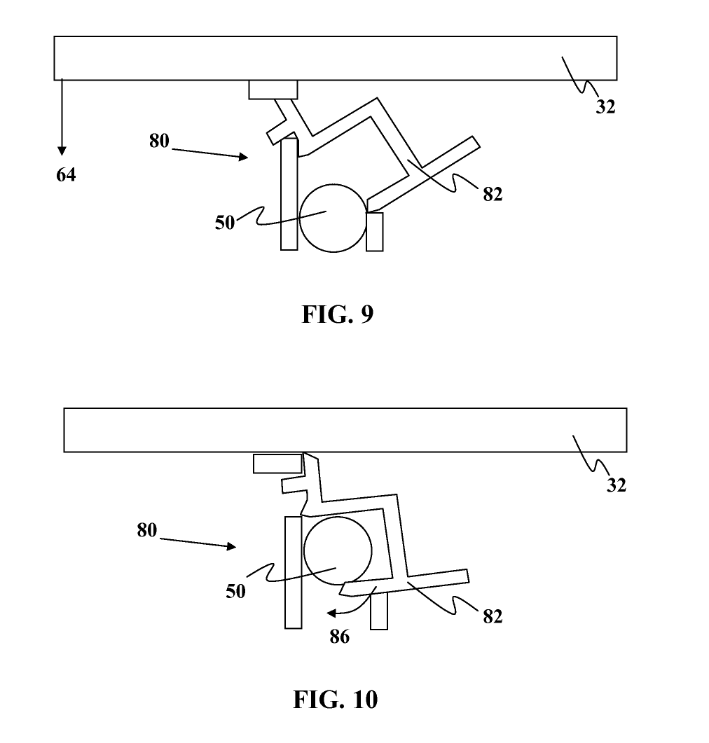

Referring now to FIG. 9, another embodiment of a locking mechanism will now be described. This embodiment shows a locking system 80 may be used to lock the module to latitudinal rails 44 and 46 or to longitudinal rails 50 and 52. The locking system 80 uses a bracketed lock device 82 which receives the rail 50 when the module 32 and the locking system 80 are lowered over rail 50 as indicated by arrow 64.

FIG. 10 shows that as the module 32 is lowered, the rail 50 will move to a position where the bracketed lock device 82 will rotate into a position below the rail 50 as indicated by arrow 86 to lock the rail 50 into position. To release the rail 50, the bracketed lock device 82 may be rotated by the end user to allow the module 32 to be lifted upwards and away.

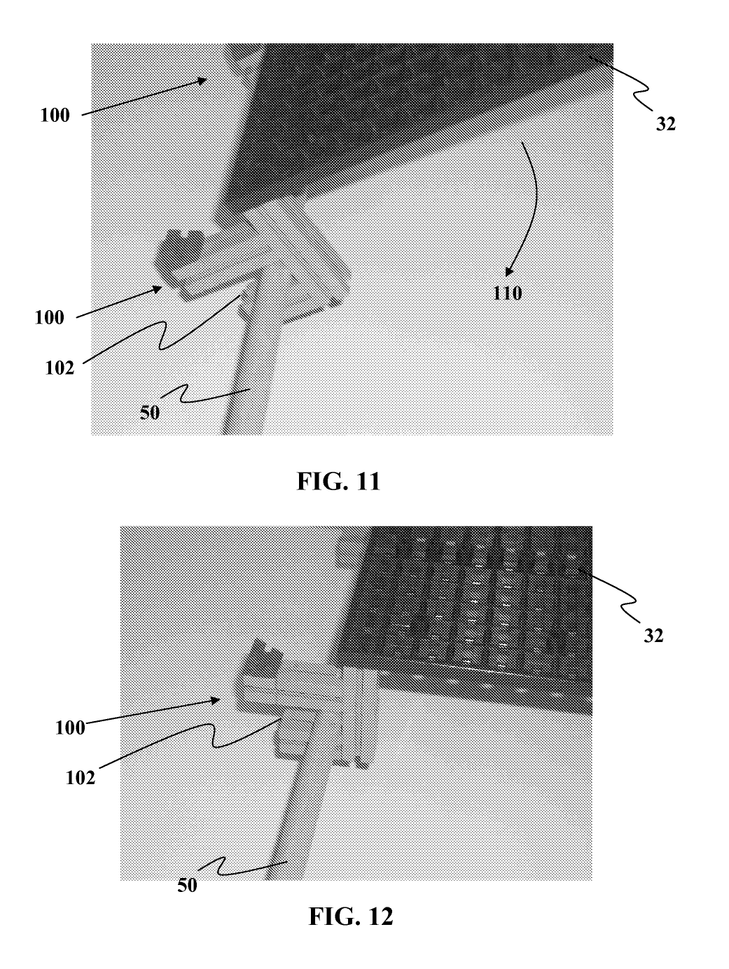

Referring now to FIG. 11, another type of module mounting hardware will now be described. FIG. 11 shows a bracket 100 mounted to the module 32. There may be two brackets 100 on each end of the module. It should be understood of course that other numbers of brackets may be used per module. The bracket 100 includes an opening 102 for receiving the rail 50. The module 32 is angled from horizontal to engage the rail 50.

FIG. 12 shows that the module 32 is lowered into position as indicated by arrow 110 in FIG. 11. FIG. 12 shows that the position allows a second type of brackets 120 to engage a rail 52 as seen in FIG. 13.

FIG. 13 shows that a second type of bracket 120 allow the module 32 to be secured to a second rail 52. These brackets 120 have opening 122 that are downward facing. The openings 102 and 122 are optionally aligned in different orientations to hold the module in placed both vertically and laterally. As seen in FIG. 13, once the brackets 100 are slid into position over the rail 50, the brackets 120 are positioned and oriented to help lock the module into position.

FIG. 14 now shows how this embodiment of mounting hardware allows a next module to be interconnected to module 32 that is already in position. The brackets 120 are mounted to be offset from the brackets 100 coming from the next module 34. They may be inside of, outside of, or in some other offset configuration relative to the brackets 100. This allows for the brackets 100 on module 34 and the brackets 120 of module 32 to both slidably engage the support rail 52. Additionally, a wedge piece 130 and 132 are positioned to help hold the modules 32 and 34 together. Wedge piece 130 is mounted to the underside of module 32. Wedge piece 132 is mounted on the tip of the bracket 100 of module 34. The wedges are positioned so that when the modules 32 and 34 are brought together, these wedge pieces 130 and 132 will engage in a mating manner to help hold the modules in place. Some pieces 130 and 132 may have cutouts and protrusions to help provide mechanical force to hold the pieces together. Others may use frictional force between surfaces on wedge pieces 130 and 132 to hold them together.

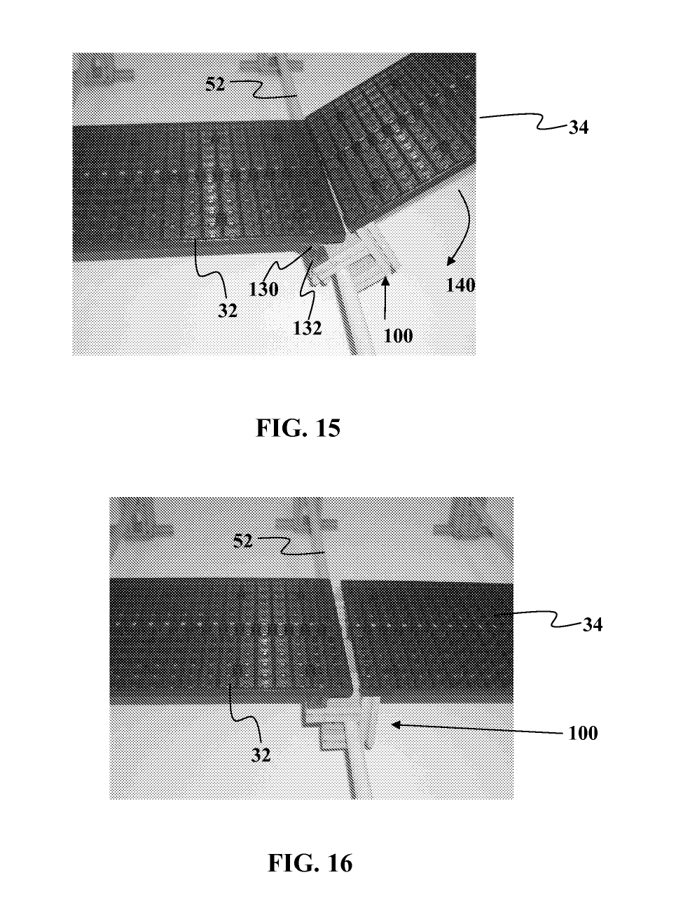

As seen in FIG. 15, the module 34 will be rotated into position as indicated by arrow 140 to position the module 34 against the support rail 52.

FIG. 16 shows that final position wherein the wedge pieces 130 and 132 of modules 32 and 34 are fully engaged.

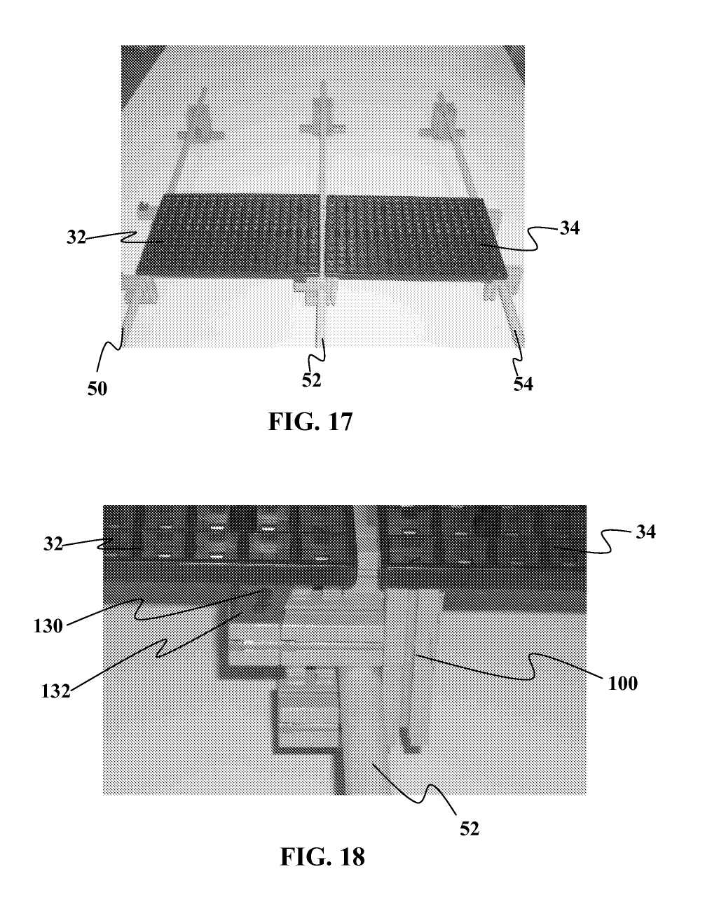

FIG. 17 shows how the modules 32 and 34 can be mounted over rails 50, 52, and 54.

FIG. 18 shows a close-up view of the wedge pieces 130 and 132. As seen in FIG. 18, the piece 130 on module 32 has an angled surface or detent feature to prevent the module 34 from pulling away. The piece 132 also has an angled surface or detent feature that mates with the angled surface of piece 130.

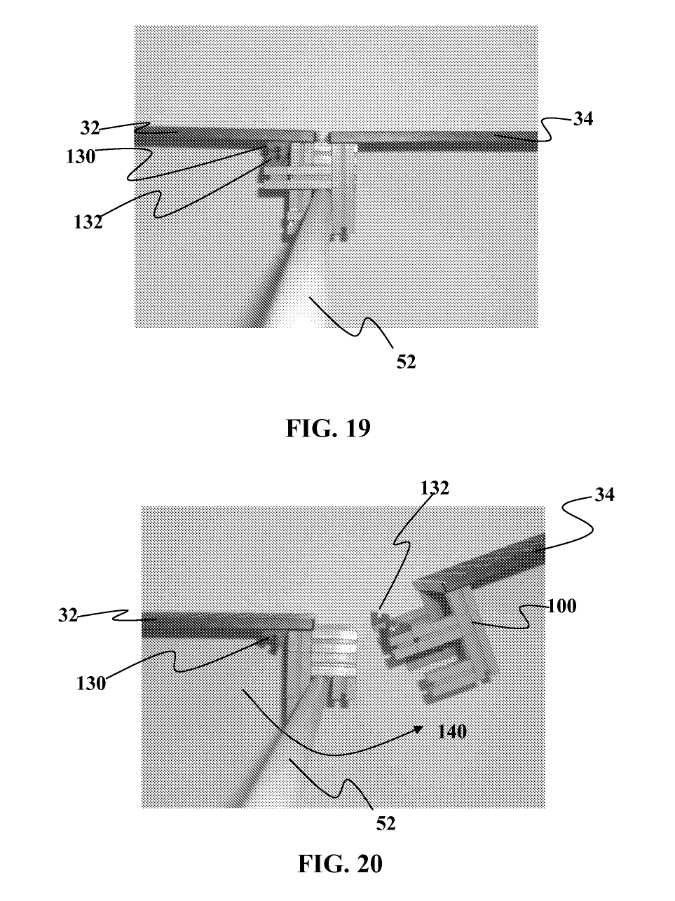

FIG. 19 shows a side view of the wedge pieces 130 and 132. It also shows how the modules 32 and 34 may be disengaged. Disengagement may occur by rotating module 34 up and away so that the wedge pieces 130 and 132 separate from one another.

FIG. 20 more clearly shows the rotational motion indicated by arrow 140. The wedge pieces 130 and 132 separated from one another. Rotating motion also lifts the bracket 120 clear of the rail 54, allowing the module 34 to be removed.

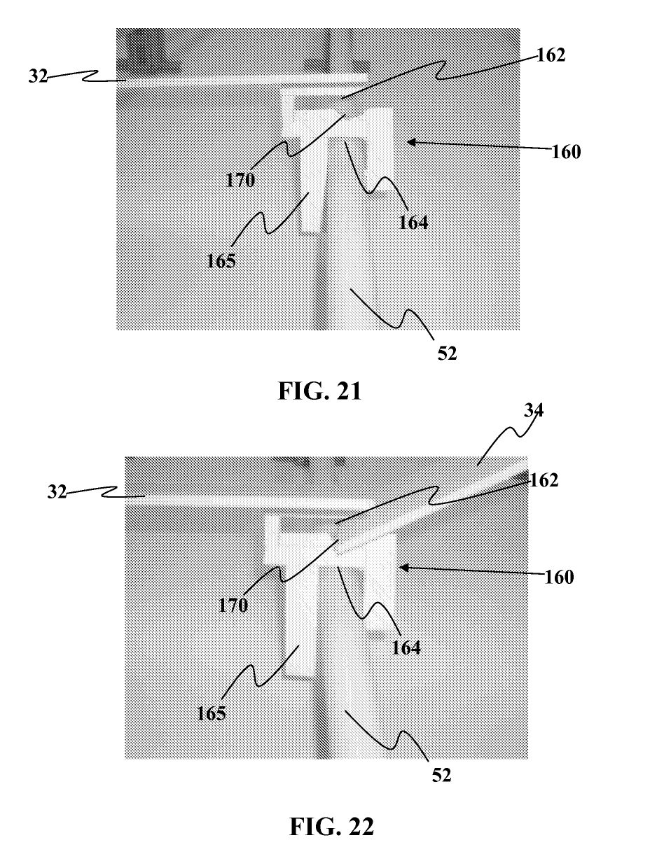

Referring now to FIG. 21, yet another embodiment of the present invention will now be described. FIG. 21 a modified bracket 160 that is, in one embodiment, mounted only along one edge of the module. As seen in FIG. 22, the other edge of the module may be without brackets. Optionally, other may have brackets that are offset in position so as not to conflict with brackets 160. FIG. 21 shows that bracket 160 includes two openings 162 and 164. First opening 162 is positioned so that is can receive the edge of another module 34. The second opening 164 is positioned to receive the rail 52. In this manner, the bracket 160 handles two functions of a) securing module 32 to the rail 52 and b) securing modules 32 and 34 together. The bracket 160 may have one extension 165 that is longer to help guide it into position. Other embodiments may have brackets wherein all extensions are of the same length.

FIG. 22 shows how the module 34 is received in opening 162. A carveout 170 allows the module 34 to be received into the opening 162 and then rotated as indicated by arrow 172. Once rotated, the module 34 may then be pushed fully into position as indicated by arrow 174. This also lowers another bracket 160 on the opposite edge of module 34 into position over rail 54 (not shown for ease of illustration). As seen in these embodiments, no clip or bracket feature on one module end is needed. By way of example and not limitation, brackets 160 are located only on one end of the module. Optionally, others may have brackets on more than one edge of the module.

It should be understood that in these “daisy-chain” connected modules, securing at least one of the end modules by way of clips, fasteners, glue, or other device. In such an embodiment, the modules in the middle of the chain are interlocked and cannot be released unless one of the end modules is released. It should be understood that there can one, two, or more brackets per module. Optionally, one bracket can hold more than one module at a time. Optionally, a bracket may be wider than a module, the same width as a module, or less than the width of a module.

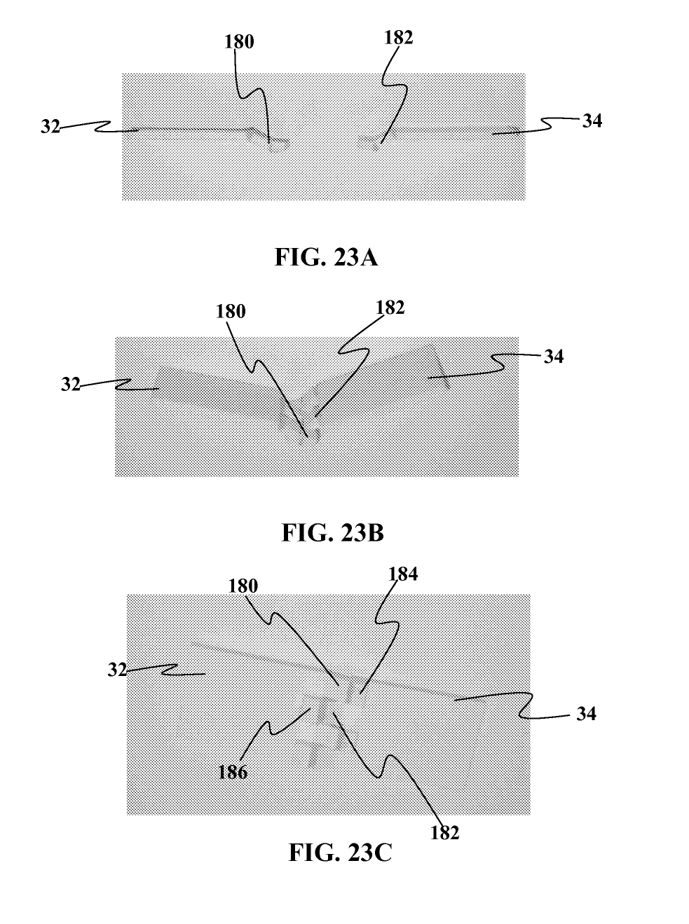

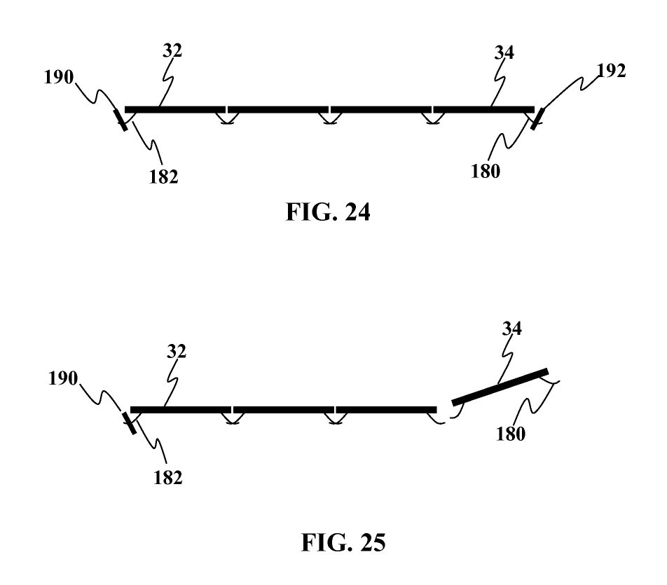

Referring now to FIGS. 23A through 23C, another locking mechanism for securing modules together will now be described. This embodiment shows that modules 32 and 34 may have fingers 180 and 182 angled and staged to engage and lock with each other. These fingers 180 and 182 may be integrally formed with the modules or they may be attached after module formation.

FIG. 23B shows that the fingers 180 and 182 from the modules may interweave between each other. A flat surface 184 and 186 from each finger may extend over a portion of the adjacent module or modules mounting hardware to hold the modules in place. This may be more clearly seen in FIG. 23C.

FIG. 23C shows that the fingers 180 and 182 are offset from one another. FIG. 23C is an underside view showing how the fingers are positioned so as not to cover areas that may otherwise be receiving sunlight. Of course, other embodiments may use fingers that overhang a portion of the top side of the module.

Referring now to FIGS. 24 and 25, it is seen that when the modules with connectors such as but not limited to those of FIGS. 23A-23C are “daisy-chained” together and then fixed in place at the ends of the chain by fasteners 190 and 192. As seen in FIG. 25, when one of the end modules 34 is released, this allows the modules to be pivoted out and released, typically one module at a time. Optionally, the modules may be angled out, translated, or otherwise moved along the same path used to attach the modules together. The motion is typically such that it is not straight downward or straight upward (relative to horizontal and/or the support beam) but is in a deliberate motion that is in a degree of freedom that is not straight down or up (and/or normal to the support beam). Some embodiments may require translation in a lateral direction before pivoting and/or angling to release the module.

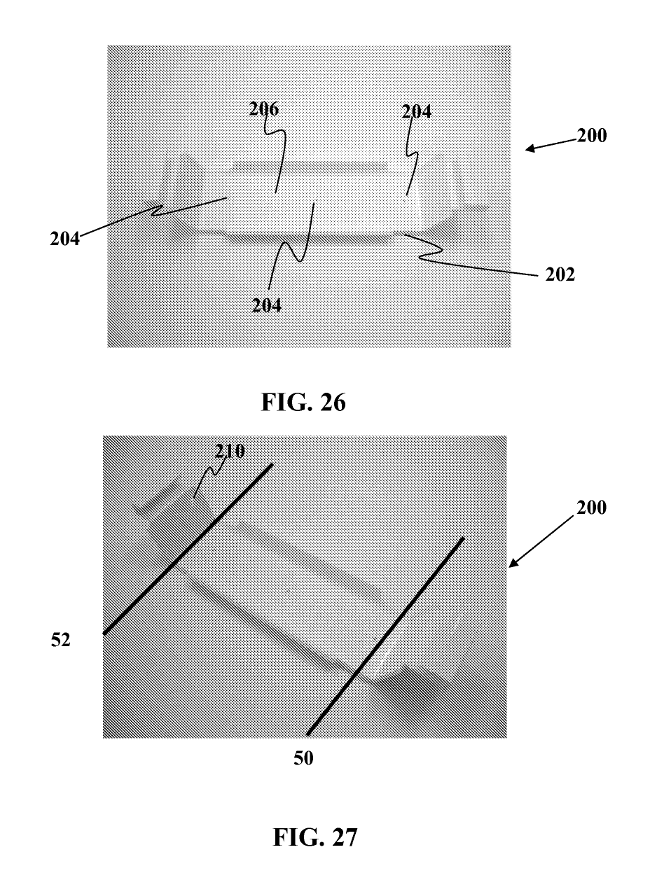

Referring now to FIG. 26, yet another embodiment of the present invention will now be described. FIG. 26 shows a universal mounting bracket 200. This bracket 200 has multiple methods of attaching a module 32 to a surface. In one aspect, the bracket 200 may have an adhesive undercoating along its underside 202. This may be revealed by a peel away membrane that reveals the adhesive. In this manner, the bracket 200 may be adhered to the mounting surface.

In another aspect, the bracket 200 has openings 204 that allow for screw, nail, staple, and/or fastener attachment of the bracket 200 to a target mounting surface. Rubber grommets may be used with the openings 204 to prevent moisture entry. Other embodiments may have a polymer or other moisture barrier surface on the underside of the module, but these are exemplary and nonlimiting. In one embodiment, the underside of the bracket 200 may be flat, textured, ribbed, honeycombed, or otherwise surface shaped to best engage that surface on which the bracket is mounted. Bracket 200 may be mounted horizontally, vertically, or at an angle relative to horizontal.

In yet another aspect, the bracket 200 may be weighed down by weights in the basket area 206. This may be a sandbag, brick, or other material to hold the bracket in position. Adhesives may also be used in area 206 to hold the sandbag or brick in place. Other may have the bag or straps for a bag integrated with the bracket 200. The edges 207 may be raised to define a volume that can be used to help contain any weight and/or ballast used therein.

In a still further aspect, the brackets 200 may be interlocked by rails 50 and 52 that may interconnect a plurality of brackets 200 together as seen in FIG. 27.

It should be understood that mounting brackets according to the present invention may use one, two, three, four, or more of the attachment methods in each bracket. Some brackets may be configured only to use two of these attachment methods. Optionally, some brackets may be configured only to use three of these attachment methods. Optionally, some brackets may be configured only to use four of these attachment methods. Optionally, some brackets may be configured to use more than four of these attachment methods or to use them in single or multiple combinations. These brackets 200 may be included in a kit with one or more solar modules so that an installer has many attachment options available and can chose the ones most suited for the particular installation. Brackets 200 may be wider than, same width as, or narrow than the modules the couple to.

FIG. 27 also shows that cutouts 210 may be incorporated into the bracket 200 to allow for wire management to guide electrical connections in an organized and supported manner beneath the module.

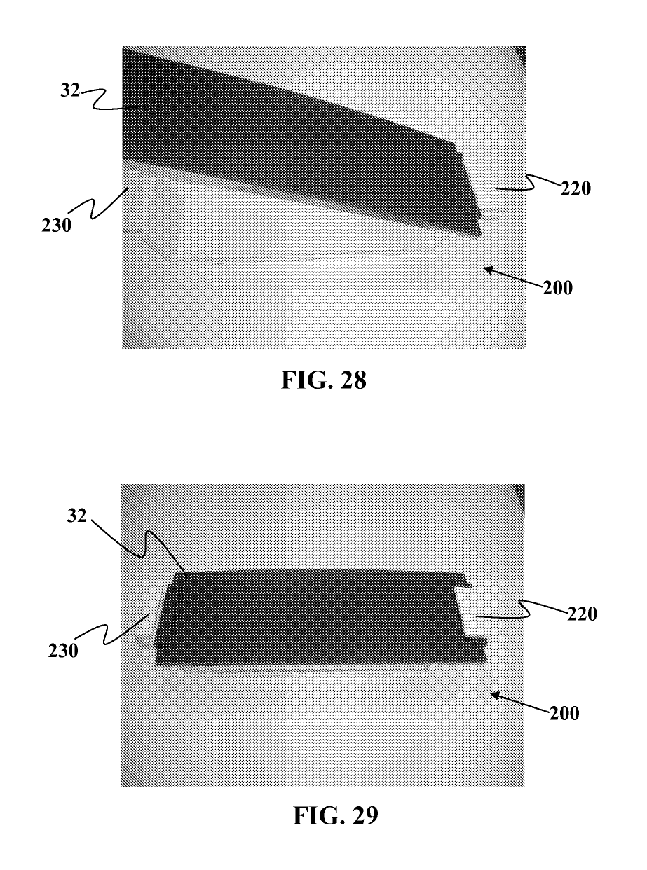

Referring now to FIG. 28, a module 32 is shown engaging a lip 220 of the bracket 200. The lip 220 is sized to be longer that the lip 230 on the other end of this embodiment of the bracket 200. The lip 220 or other feature may be integrally formed with the bracket so that the bracket provides features for module/bracket attachment and module/support surface attachment.

As seen in FIG. 29, this longer lip 220 allows that module 32 to be positioned flat against the bracket 200.

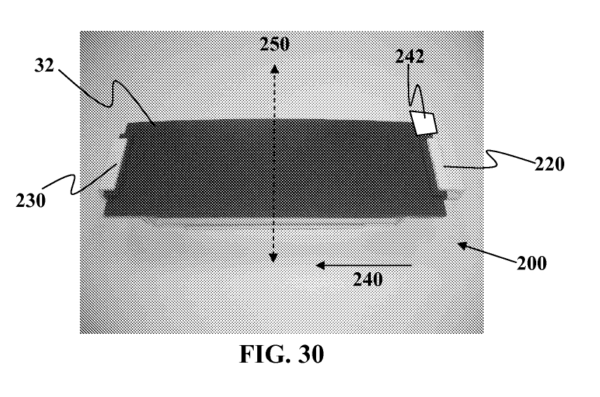

As seen in FIG. 30, the module 32 is moved as indicated by arrow 240 to engage the lip 230 while still being retained by lip 220. By way of nonlimiting example, a bolt, spacer, clip, or other device may be used with lip 220 to prevent the module from sliding out. Alternatively, the bracket is mounted on an angle roof, the direction of gravity preventing the module from slide out of lip 230. Two or more brackets 200 may be used with each module 32. Electrical edge connector boxes or connector boxes on the underside prevent motion in the axis 250 as they will hit the bracket 200 and prevent total disconnection of the module in the axis. Of course, it should be understood that in some embodiments, the bracket 200 does not span the entire length of the module. Some may be shorter and are attached to the module by adhesive or other suitable fastener.

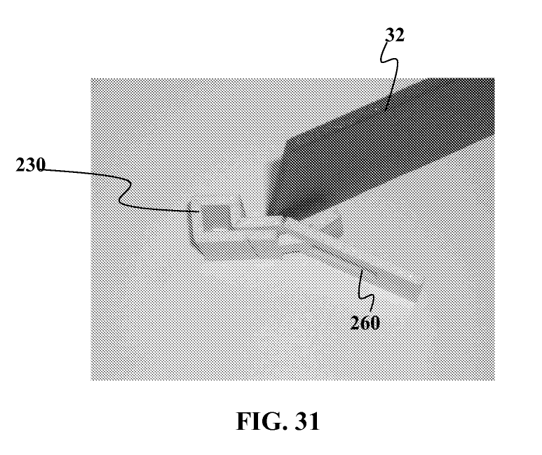

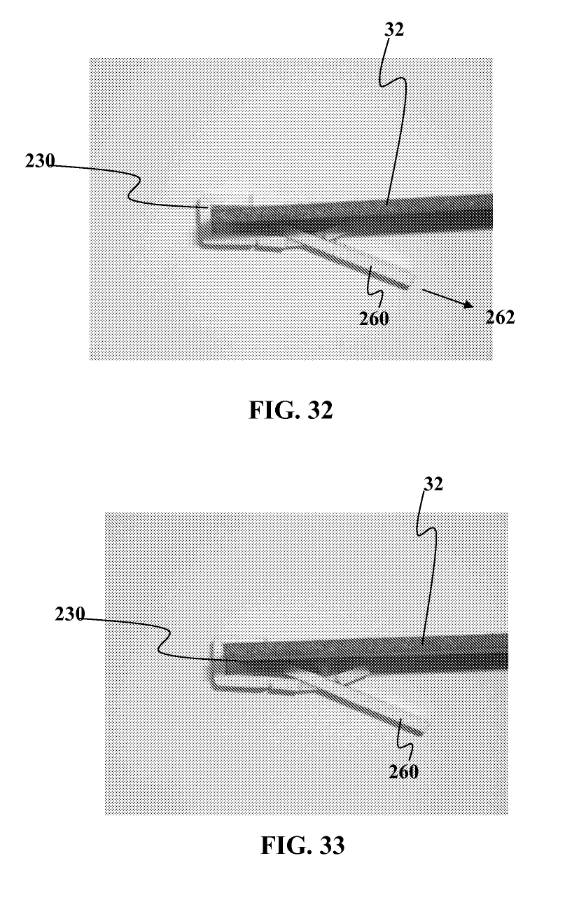

FIGS. 31 through 33 show that the lips 220 and/or 230 may include additional fasteners 260 that may be retracted to exert force that helps to pinch the module in place. The pinching is activated by the pushing of the clip 230 in direction 262. In the present embodiment, 260 is part of the bracket 200. Part 230 is free-floating, and slid down slot in 260 until it locks into place.

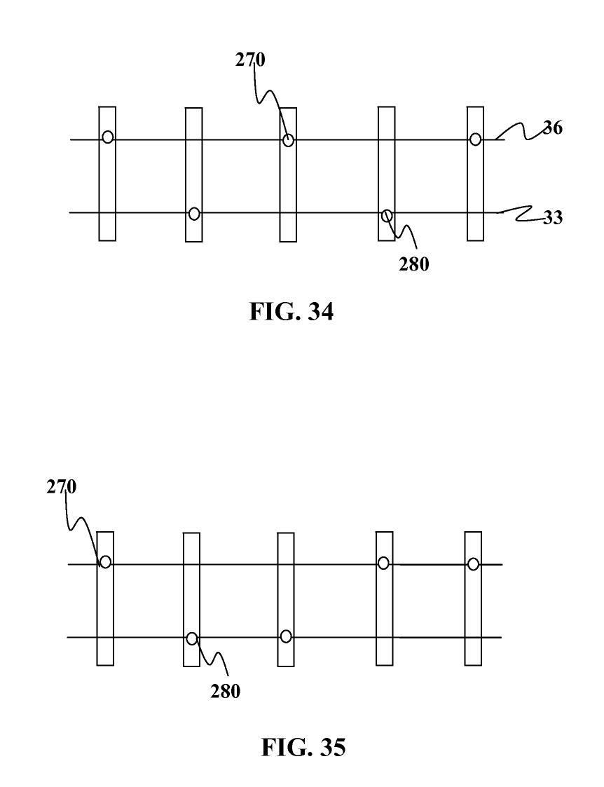

Referring now to FIGS. 34 and 35, yet another embodiment of the present invention will now be described. This embodiment shows that ground supports for mounts such as that of FIG. 3 may be alternated to reduce the amount of beams needed without significantly reducing mechanical strength. This embodiment in FIG. 34 uses beams 270 and 280 that alternate between each horizontal beam

FIG. 35 shows that the alternating of beams 270 and 280 occur every two horizontal beams. It should be understood that other patterns may also be used.

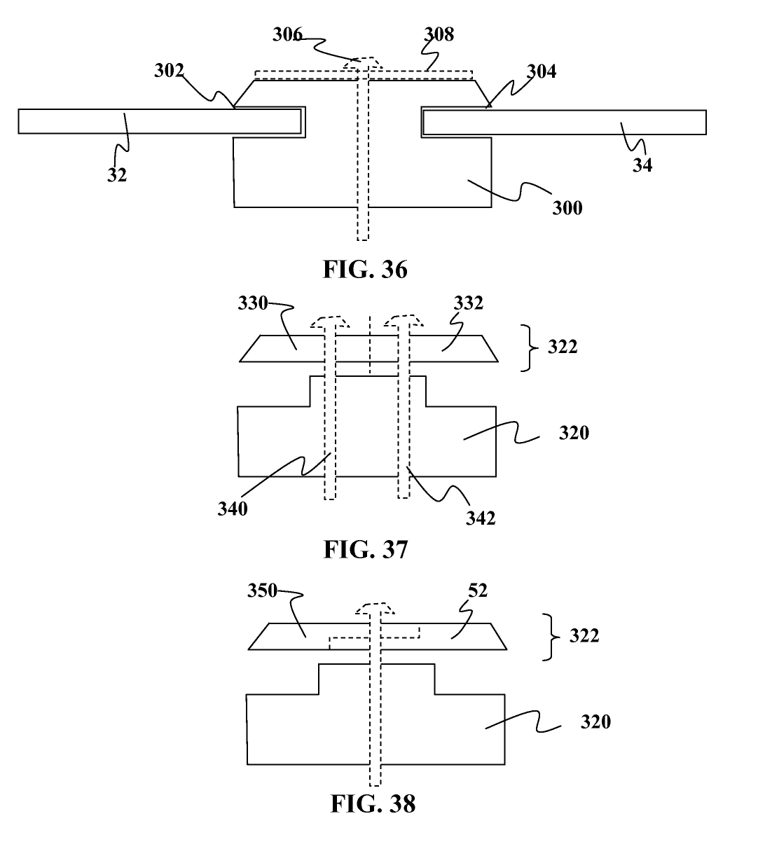

Referring now to FIG. 36, a still further embodiment of the present invention will now be described. This embodiment is a module attachment device that may be used to secure to a roof or other surface. It is of particular use on metal roofs with undulating ridges, but of course, is not limited to such structures.

FIG. 36 shows an extruded polymer or rubber support 300 that include an opening 302 and 304 for receiving modules 32 and 34. The support 300 may include a bolt or other fastener 306 that pass through the entire support 300 to secure to a surface on the underside of the support 300. There is no moisture entry issue as the support 300 is of a polymer or rubber material that can be compressed to seal around the penetration point. Optionally, the support 300 may be made of a more rigid material such as but not limited to hard plastic, steel, aluminum, copper, ceramic or other material. There may simply be a polymer or rubber coating on the surface that interfaces with the roof surface or other mounting surface to provide a moisture barrier. Other embodiments may an adhesive in addition to or in place of any attachment already mounted on the support 300. There may optionally also be a metal or rigid support piece 308 over the support 300.

FIG. 37 shows that in another embodiment, support 300 comprises of a base 320 and a top piece 322. The top piece 322 may be made of a more rigid material such as but not limited to hard plastic, steel, aluminum, copper, ceramic or other material. There may simply be a polymer or rubber coating on the surface that interfaces with the module. The top piece 322 may optionally comprise of two pieces 330 and 332. This allows for separate attachment of each module and this allows one to be installed first while the next module (which may be in a different column or different row) to be installed in a different sequence while fully tightening the first one in place. There may be two bolts or fasteners 340 and 342 to secure each of the pieces.

FIG. 38 also shows another embodiment wherein the top piece 322 comprises of two pieces. In this embodiment, there may be stair step configuration for pieces 350 and 352. There may be one or two bolts/fasteners. As they may be one behind the other, only one is visible in the perspective of FIG. 38.

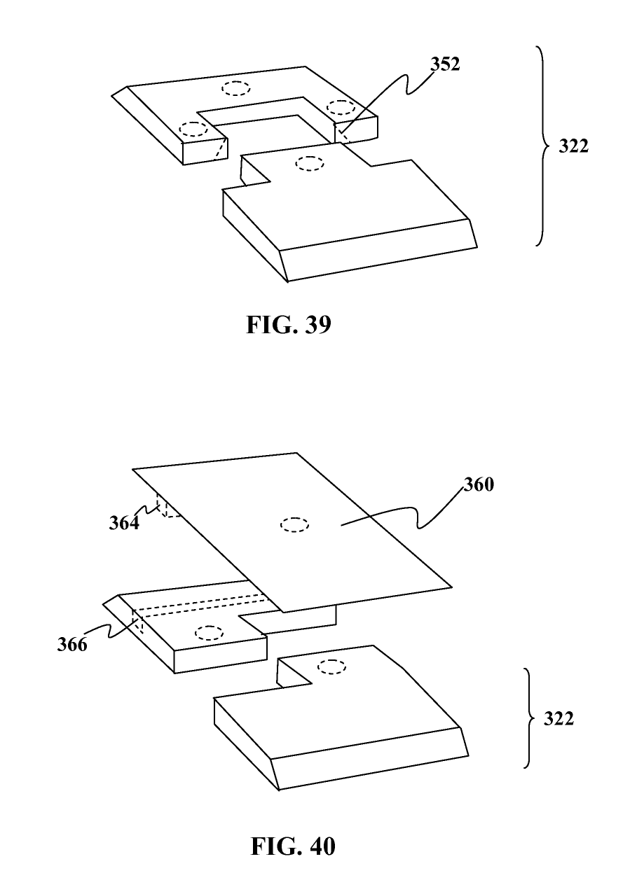

FIG. 39 shows a perspective view another embodiment of another two piece design for piece 322. The holes in phantom show possible bolt locations. Each piece may have one or more bolts. FIG. 39 also shows that some embodiments may be dovetailed in the vertical direction as indicated by line 352 which shows that the piece 322 may be shaped to mate and prevent upward lifting apart. The opposing piece may also be shaped to match the dovetailed shape.

FIG. 40 shows a perspective view another embodiment of another two piece design for piece 322. The holes in phantom show possible bolt locations. Each piece may have one or more bolts. FIG. 40 as well as another of the other embodiments may also use a metal or rigid piece 360 to provide more rigid holding force to the top piece 322. Again, if using a rigid material, they may optionally be coated with a polymer material to help couple to without damaging the module. A protrusion 364 and lock-in groove 366 may optionally be included to facilitate engagement of the pieces.

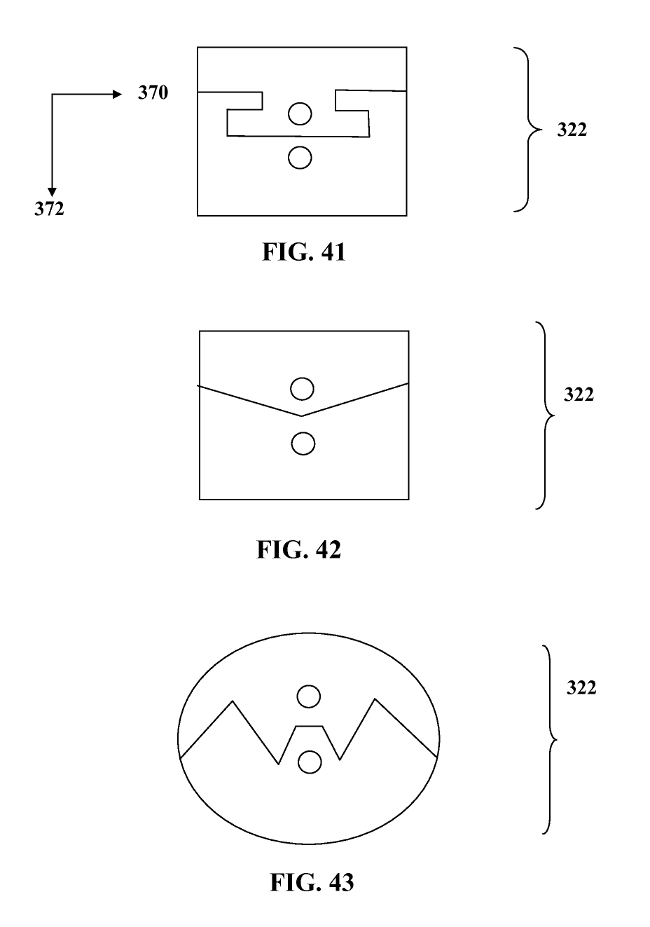

FIGS. 41, 42, and 43 show top down views of other top pieces 322. FIG. 41 is particularly useful as it provides a shape where one piece is laid in first and the second is laid in vertically to mesh into the cutout. Its shape helps to hold the top piece 322 in placed to resist tension or compression in both the axis 370 and 372.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the module, it should be understood that other material may be used and some multi-laminate materials may be used in place of or in combination with the glass. Some embodiments may use flexible top layers or coversheets. By way of nonlimiting example, the backsheet is not limited to rigid modules and may be adapted for use with flexible solar modules and flexible photovoltaic building materials. Embodiments of the present invention may be adapted for use with superstrate or substrate designs.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. Provisional Application Ser. No. 60/969,694 filed Sep. 3, 2007 is fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A photovoltaic module mounting system comprising:
at least one photovoltaic module;
at least a first type of mounting bracket in contact with the module;
at least a second type of mounting bracket on an adjacent module, wherein the brackets are configured to interlock and connect multiple modules together.

2. The system of claim 1 wherein the module is a frameless module.

3. The system of claim 1 wherein the first type of mounting bracket is configured so that the bracket can only be disengaged from the second type of mounting bracket by a pivoting motion of one bracket relative to one another.

4. The system of claim 1 wherein the bracket is configured to slidably engage a mounting structure.

5. The system of claim 1 wherein the bracket includes an angled portion that mates with an angled portion on another bracket.

6. The system of claim 1 wherein the brackets on one module are offset from brackets on another module so as not interfere with each other.

7. The system of claim 1 wherein the brackets on one module and brackets on another module both engage on another and both simultaneously engage a mounting structure.

8. The system of claim 1 wherein the bracket is configured to slidably engage a mounting structure and simultaneously engage a bracket of another module.

9. The system of claim 1 wherein the brackets on one module and brackets on another module both engage on another mate in a configuration that prevent the modules from pivoting upward beyond a substantially horizontal plane.

10. The system of claim 1 wherein a plurality of modules are coupled together by brackets which pivot together to define a string of modules that are locked in position, wherein only the modules at a first end and a second end of the string of modules are fixedly secured.

11. A universal mounting assembly comprising:
a bracket configured to provide attachment of a module to the bracket and then the bracket to mounting structure, wherein attachment of bracket to mounting structure is by way of at least two possible attachment methods.

12. The assembly of claim 10 wherein the bracket is configured wherein attachment of bracket to mounting structure is by way of at least three possible attachment methods.

13. The assembly of claim 10 wherein the bracket is configured wherein attachment of bracket to mounting structure is by way of at least four possible attachment methods.
